(19) United States
(12) Patent Application Publication
(10) Pub. No.: US 2025/0385176 A1
(43) Pub. Date: Dec. 18, 2025

(54) TILTED SUPER VIAS

(71) Applicant: Applied Materials, Inc., Santa Clara, CA (US)

(72) Inventors: Abhilash Velluridathil Thazhathidathil, Valkenswaard (NL); Martinus Maria Berkens, Waalre (NL); Vinod Reddy, San Jose, CA (US); Simon Johannes Klaver, Weert (NL); Amol Gupta, Tampa, FL (US)

(73) Assignee: Applied Materials, Inc., Santa Clara, CA (US)

(21) Appl. No.: 18/741,085

(22) Filed: Jun. 12, 2024

(51) Int. Cl. H01L 23/528; H01L 21/768; H01L 23/522; H01L 23/532

(52) U.S. Cl. CPC H01L 23/528; H01L 21/76816; H01L 23/5226; H01L 23/5329

(57) ABSTRACT

Exemplary semiconductor structures may include a substrate, a first interconnect, an insulator material, and a second interconnect. The second interconnect may be separated from the first interconnect by the insulator material. The structures may include a tilted super via connecting the first interconnect to the second interconnect. The structures may include a third interconnect disposed between the first interconnect and the second interconnect. The tilted super via may bypass the third interconnect.

### TECHNICAL FIELD

The present technology relates to semiconductor processes and semiconductor structures. More specifically, the present technology relates to semiconductor structures including tilted super vias and methods of forming the same.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor structures may include a substrate, a first interconnect, an insulator material, and a second interconnect. The second interconnect may be separated from the first interconnect by the insulator material. The structures may include a tilted super via connecting the first interconnect to the second interconnect. The structures may include a third interconnect disposed between the first interconnect and the second interconnect. The tilted super via may bypass the third interconnect.

In some embodiments, the first interconnect and the second interconnect may be vertically separated by the insulator material. The first interconnect and the second interconnect may be horizontally separated by the insulator material. The first interconnect and the second interconnect may be routing layers characterized by different pitches. The first interconnect may be parallel to the second interconnect. The structures may include a second tilted super via connecting a second portion of the first interconnect to a second portion of the second interconnect. The tilted super via and the second tilted super may be nonparallel. The first interconnect and the second interconnect may be connected without an intermediate layer. The tilted super via may be characterized by an angle relative to the substrate of less than or about 90°. The tilted super via may be characterized by an angle relative to the substrate of greater than or about 60°. The insulator material may be or include a silicon-containing material.

Some embodiments of the present technology may encompass semiconductor processing methods. The methods may include forming a semiconductor structure. The semiconductor structure may include a substrate, a first interconnect, an insulator material, and a second interconnect. The second interconnect may be separated from the first interconnect by the insulator material. The methods may include etching a non-orthogonal feature into the semiconductor structure. The methods may include forming a tilted super via in the non-orthogonal feature that connects the first interconnect to the second interconnect.

In some embodiments, the first interconnect may be parallel to the second interconnect. The first interconnect and the second interconnect may be connected without an intermediate layer. The semiconductor structure may further include a third interconnect disposed between the first interconnect and the second interconnect. The tilted super via may bypass the third interconnect. The tilted super via may be characterized by an angle relative to the substrate of between about 60° and about 89°. The methods may include etching a second non-orthogonal feature into the semiconductor structure. The second non-orthogonal feature may be unparallel with the non-orthogonal feature. The methods may include forming a second tilted super via in the non-orthogonal feature that connects a second portion of the first interconnect to a second portion of the second interconnect.

Some embodiments of the present technology may encompass semiconductor structures. The structures may include a substrate, a first metal-containing routing layer, an insulator material, and a second metal-containing routing layer. The second metal-containing routing layer may be parallel to the first metal-containing routing layer and vertically separated from the first metal-containing routing layer by the insulator material. The structures may include a first tilted super via connecting a first portion of the first metal-containing routing layer to a first portion of the second metal-containing routing layer. The structures may include a second tilted super via connecting a second portion of the first metal-containing routing layer to a second portion of the second metal-containing routing layer. The first tilted super via and the second tilted super via may be unparallel.

In some embodiments, the tilted super via may bypass a third metal-containing routing layer disposed between the first metal-containing routing layer and the second metal-containing routing layer. The first metal-containing routing layer and the second metal-containing routing layer may be connected without an intermediate routing layer. The tilted super via may be characterized by an angle relative to the substrate of between about 60° and about 89°.

Such technology may provide numerous benefits over conventional systems and techniques. For example, the processes may etch non-orthogonal features in structures such that tilted super vias may be formed. The tilted super vias may connect metal-containing features that are aligned on different pitches. The tilted super vias may obviate the need for intermediate routing layers that may reduce device performance. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2A shows a side view of one embodiment of an exemplary processing system according to some embodiments of the present technology.

FIG. 2B shows a top plan view of an exemplary processing chamber according to some embodiments of the present technology.

FIG. 3 shows exemplary operations in a method according to some embodiments of the present technology.

FIGS. 4A-4C show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As structures grow in the number of transistors being formed, the aspect ratios of layers and other features increase, sometimes dramatically. Additionally, with the increased number of transistors and reduced aspect ratios of layers and features, routing congestion becomes a difficult problem. Many routing layers do not align (or intersect) and require the use of intermediate routing layers to connect these unaligned routing layers.

Conventional technologies utilize traditional vias etched vertically or perpendicular to the routing layers to be connected. However, since some routing layers may be on different routing pitches (or routing grids), the use of an intermediate routing layer is necessary. The intermediate routing layer may be a short length of routing to connect two traditional vias to unaligned routing layers. Conventional technologies may also utilize super vias to bypass intermediate layers when routing layers to be connected lie on the same routing pitch. However, the routing layers to be connected must be aligned or else the super via will fail.

The present technology overcomes these issues by forming tilted super vias. The tilted super vias may connect routing layers on different routing pitches without the use of an intermediate layer. The tilted super via may be formed in a non-orthogonal feature etched in the structure. By eliminating the intermediate layer, the tilted super via may save on parasitic of the intermediate layer that is able to be bypassed. Additionally, by avoiding the intermediate layer, resistance and capacitance may be reduced. Further, by avoiding the intermediate layer, routing congestion may be reduced, which may help with routing congestion in the structure, freeing space for additional structures or features.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described.

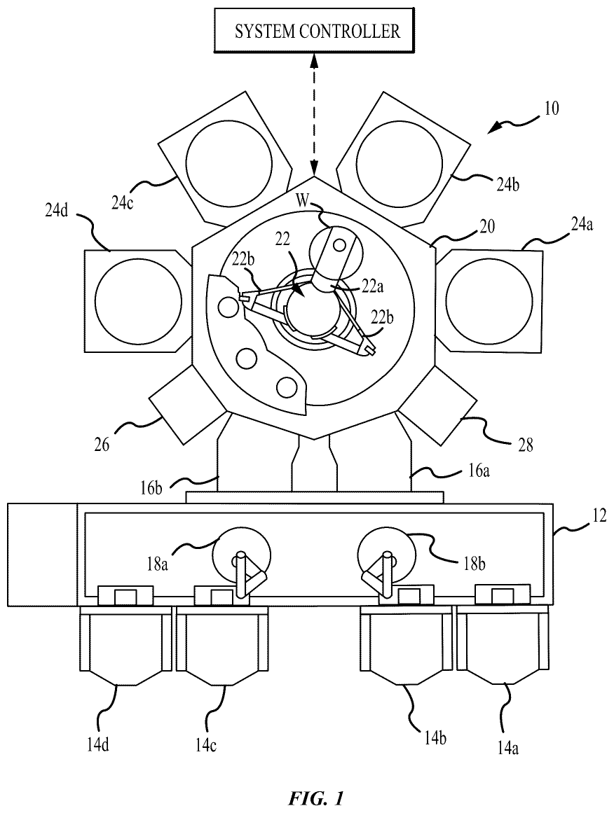

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

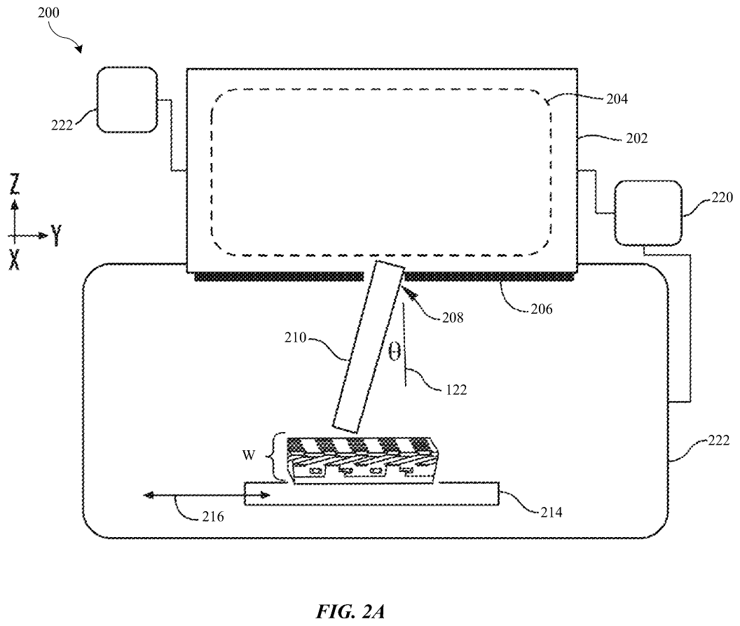

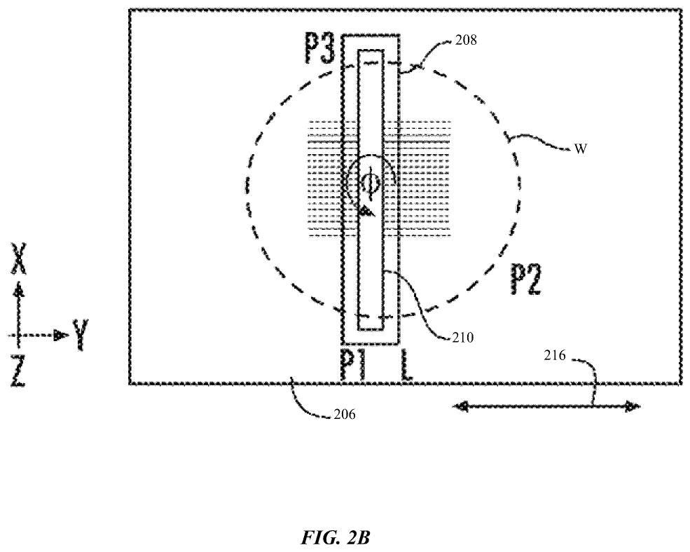

FIG. 2A illustrates a schematic cross-sectional view of an exemplary processing apparatus 200 suitable for patterning a material layer disposed on a substrate W in the processing apparatus 200. The processing apparatus 100 represents a processing apparatus for etching portions of a substrate, such as an insulator layer. The processing apparatus 200 may be a plasma based processing system having a plasma chamber 202 for generating a plasma 204 therein by any convenient method as known in the art. An extraction plate 206 may be provided as shown, having an extraction aperture 208, where a selective etching may be performed to reactively etch an insulator layer with respect to a mask material. A substrate W including, for example, the aforementioned structure, may be disposed in the process chamber 222. A substrate plane of the substrate W may be represented by the X-Y plane of the Cartesian coordinate system shown, while a perpendicular to the plane of the substrate W lies along the Z-axis (Z-direction).

During an angled reactive ion beam etching operation, an ion beam 210 may be extracted through the extraction aperture 208 as shown. As illustrated in FIG. 2A, the trajectory of the ion beam 210 forms a non-zero angle of incidence with respect to perpendicular line 122, shown as θ. The trajectories of ions within the ion beam 210 may be mutually parallel to one another or may lie within a narrow angular range, such as within 10 degrees of one another or less. Thus, the value of 0 may represent an average value of incidence angle where the individually trajectories vary up to several degrees from the average value. The ion beam 210 may be extracted when a voltage difference is applied using bias supply 220 between the plasma chamber 202 and substrate W as in known systems. The bias supply 220 may be coupled to the process chamber 222, for example, where the process chamber 222 and substrate W are held at the same potential. In embodiments, the ion beam 210 may be extracted as a continuous beam or as a pulsed ion beam as in known systems. For example, the bias supply 220 may be configured to supply a voltage difference between plasma chamber 202 and process chamber 222, as a pulsed DC voltage, where the voltage, pulse frequency, and duty cycle of the pulsed voltage may be independently adjusted from one another.

In embodiments, for example, the ion beam 210 may be provided as a ribbon ion beam having a long axis extending along the X-direction of the Cartesian coordinate system shown in FIG. 2B. During operation, a mask material may be oriented in a manner where the openings 206 are arranged in rows that may be generally aligned with rows of the active device regions on substrate W, as viewed in the X-Y plane. The rows of the openings 206 may be displaced in the X-Y plane with respect to the rows of the active device regions on substrate W. The projection in the X-Y plane of the trajectories of ions of the ion beam 210 is shown by the arrows. By scanning a substrate stage 214 including substrate W with respect to the extraction aperture 208, and thus with respect to the ion beam 210 along the scan direction 216, the ion beam 210 may etch a set of angled vias oriented at a non-zero angle of inclination with respect to the perpendicular line 122. The ion beam 210 may be composed of any convenient gas mixture, including inert gas, reactive gas, and may be provided in conjunction with other gaseous species in some embodiments. In embodiments, the ion beam 210 and other reactive species may be provided as an etch recipe to the substrate W so as to perform a directed reactive ion etching of targeted sidewalls of the substrate W. Such an etch recipe may use known reactive ion etch chemistries for etching materials such as oxide or other materials as known in the art. The etch recipe may be selective with respect to the mask material on the substrate W, so as to remove insulator material on the substrate W, while not etching the mask material, or etching the mask material to a lesser extent.

In this example of FIG. 2B, the substrate W is a circular wafer, such as a silicon wafer, the extraction aperture 208 is an elongated aperture, having an elongated shape. The ion beam 210 may be provided as a ribbon ion beam extending to a beam width along the X-direction, where the beam width may be adequate to expose an entire width of the substrate W, even at the widest part along the X-direction. Exemplary beam widths may be in the range of greater than or about 10 cm, greater than or about 20 cm, greater than or about 30 cm, or more while exemplary beam lengths along the Y-direction may be in the range of greater than or about 3 mm, greater than or about 5 mm, greater than or about 10 mm, greater than or about 20 mm, or more.

As also indicated in FIG. 2B, the substrate W may be scanned in the scan direction 216, where the scan direction 216 lies in the X-Y plane, such as along the Y-direction. Notably, the scan direction 216 may represent the scanning of substrate W in two opposing (e.g., 180 degrees) directions along the Y-direction, or just a scan toward the left or a scan toward the right. As illustrated in FIG. 2B, the long axis of ion beam 210 may extend along the X-direction, perpendicularly to the scan direction 216. Accordingly, an entirety of the substrate W may be exposed to the ion beam 210 when scanning of the substrate W takes place along a scan direction 216 to an adequate length from a left side to right side of substrate W as shown in FIG. 2B.

As also shown in FIG. 2B, the exposure of substrate W to the ion beam 210 may take place when the substrate W is scanned while disposed at a first rotational position as indicated by the position P1 on substrate W being located under the location L on the extraction plate 206. For example, the position P1 may correspond to the position of a notch or a flat on a wafer. In accordance with various embodiments, at least one scan may be performed along the scan direction 216 to form vias, while the substrate W is positioned at a fixed rotational position. Because the ion beam 210 may form a non-zero angle of incidence with respect to the perpendicular line 122, etching of the vias ay proceed in a manner generating vias having an axis forming an angle of inclination oriented generally along the non-zero angle of incidence, also shown as θ in the figures depicting contact vias. In accordance with various non-limiting embodiments, the value of θ may be less than or about 30 degrees, and in particular embodiments may lie between about 20 degrees and about 30 degrees.

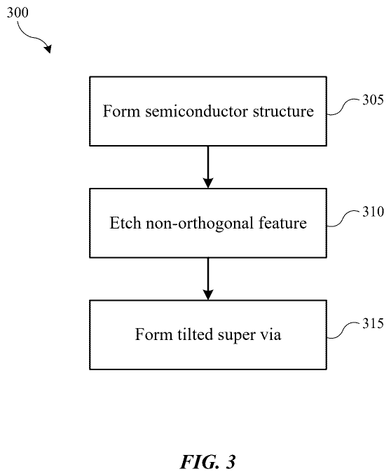

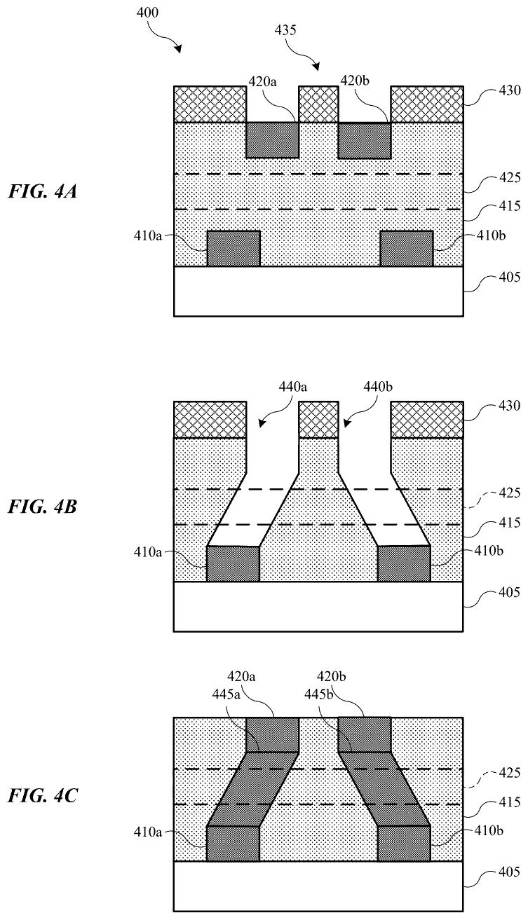

The chamber discussed previously may be used in performing exemplary methods, including etching methods, although any number of chambers may be configured to perform one or more aspects used in embodiments of the present technology. Turning to FIG. 3, exemplary operations in a method 300 according to embodiments of the present technology are shown. Method 300 may include one or more operations prior to the initiation of the method, including front end processing, deposition, etching, polishing, cleaning, or any other operations that may be performed prior to the described operations. The methods may include a number of optional operations, which may or may not be specifically associated with some embodiments of methods, according to embodiments of the present technology. For example, many of the operations are described in order to provide a broader scope of the processes performed, but are not critical to the technology, or may be performed by alternative methodology as will be discussed further below. Method 300 may describe operations shown schematically in FIGS. 4A-4C, the illustrations of which will be described in conjunction with the operations of method 300. It is to be understood that the figures illustrate only partial schematic views, and a substrate may contain any number of additional materials and features having a variety of characteristics and aspects as illustrated in the figures.

Method 300 may or may not involve optional operations to develop the semiconductor structure to a particular fabrication operation. It is to be understood that method 300 may be performed on any number of semiconductor structures 400 or substrates 405, as illustrated in FIG. 4A, including exemplary structures on which one or more tilted super vias may be formed. As used throughput the present disclosure, a titled super via may be a via that connects two interconnects, such as interconnects that are not aligned (e.g., horizontally aligned and/or vertically aligned) or on different routing pitches, bypassing an intermediate interconnect that may conventionally be used as in intermediate interconnect. The tilted super vias of the present disclosure may include an upper center point of the via that is not vertically aligned with a bottom center point of the vias. As illustrated in FIG. 4A, substrate 405 may include a first interconnect 410, such as a first metal-containing feature (e.g., a metal routing layer) or a silicon-containing material (e.g., polysilicon), and a second interconnect 420, such as a second metal-containing feature (e.g., a metal routing layer) or a silicon-containing material (e.g., polysilicon). The first interconnect 410 may include a first portion 410a and a second portion 410b. Similarly, the second interconnect 420 may include a first portion 420a and a second portion 420b. As illustrated in FIG. 4A the spacing between portions of the first interconnect 410 and the second interconnect 420 differ such that the first interconnect 410 and the second interconnect 420 do not align. The first interconnect 410 and the second interconnect 420 may be separated by an insulator material 415. The insulator material 415 may be or include a silicon-containing material, such as silicon oxide, for example. As illustrated in FIG. 4A, the first interconnect 410 and the second interconnect 420 may be vertically separated, such as by the insulator material 415. Additionally, the first interconnect 410 and the second interconnect 420 may be horizontally separated, such as by the insulator material 415. That is, the first interconnect 410 and the second interconnect 420 may be formed at different pitches in structure 400. As illustrated in FIG. 4A, the first interconnect 410 may be formed at a wider spacing than the second interconnect 420. However, it is contemplated that the first interconnect 410 may alternatively be formed at a narrower or other irregular spacing relative to the second interconnect 420. In embodiments, and as illustrated in FIG. 4A, the first interconnect 410 may be parallel to the second interconnect 420.

The structure 400 may also include a third interconnect 425, such as a third metal-containing feature (e.g., a metal routing layer) or a silicon-containing material (e.g., polysilicon). The third interconnect 425 may also be disposed within the insulator material 415. The third interconnect 425 may be disposed between the first interconnect 410 and the second interconnect 420. The third interconnect 425 may be perpendicular to either or both of the first interconnect 410 and the second interconnect 420.

Further, a mask material 430, which may be patterned to form an aperture 435 extending through a thickness of the mask material 430, may be disposed over the insulator material 415 and/or the second interconnect 420. The aperture 435 may expose the underlying materials and may allow for one or more features, such as holes or trenches, to be formed through the underlying materials. Although only a single aperture 435 is illustrated, it is to be understood that exemplary structure 400 may include any number of apertures across the substrate 405. Any of the processing to form structure 400 may be performed in chambers or system tools as previously described, or may be performed in different chambers on the same system tool, which may include the chamber in which the operations of method 300 are performed.

Method 300 may be performed to etch or otherwise remove portions of the layers of material underlying mask material 430 and exposed through aperture 435. In embodiments, method 300 may include removing a portion of the second interconnect 420 and/or the insulator material 415 to form a feature 440, such as a hole, trench, or via, through the second interconnect 420 and/or the insulator material 415. The formation of the feature 440 through the second interconnect 420 and/or the insulator material 415 may expose the underlying material, such as the first interconnect 410.

Since the structure 400 may include multiple routing layers, such as first interconnect 410 and second interconnect 420, with different pitches (or alignments), multiple features 440 may be formed. For example, individual wires of first interconnect 410 and individual wires of second interconnect 420 may be spaced apart at different intervals such that only some of the individual wires of first interconnect 410 and individual wires of second interconnect 420 align. Therefore, other wires of first interconnect 410 and second interconnect 420 may be unaligned. In embodiments, due to the irregular spacing and unalignment of the routing layers, such as first interconnect 410 and second interconnect 420, multiple features 440 may be etched. Additionally, pairs of the features 440 may be unparallel to one another, such as in the vertical direction. For example, a first feature 440a may be etched between the first portion 410a, such as a first wire, of the first interconnect 410 and the first portion 420a, such as a first wire, of the second interconnect 420. Similarly, a second feature 440b, such as a second wire, may be etched between the second portion 410b of the first interconnect 410 and the second portion 420b, such as the second wire, of the second interconnect 420. Since the first interconnect 410 and the second interconnect 420 may be unaligned with different spacings, first feature 440a and second feature 440b may be characterized by different angles relative to the substrate 405. As such, first feature 440a and second feature 440b may be unparallel.

At operation 305, method 300 may include forming the structure 400 previously discussed. The structure 400 may include the substrate 405, the first interconnect 410, the insulator material 415, and the second interconnect 420. Additional materials, such as the mask material 430, may also be formed and optionally patterned during operation 305. It is contemplated that the structure 400 may include any additional layers or materials used or useful in semiconductor processing. For example, the insulator material 415 may include a plurality of different insulator materials as distinct layers in the structure 400.

As illustrated in FIG. 4B, at operation 310, method 300 may include etching a feature 440 into the structure 400. For example, operation 300 may include etching feature 440 in the structure 400. The feature 440 may be non-orthogonal relative to the substrate 405. That is, the feature 440, such as a length of the feature 440, may be tilted or at a non-right angle relative to the substrate 405, such as an upper surface of the substrate 405. The feature 440 may be formed using any useful etching or removal method. In embodiments, processing apparatus 200 may be used to etch feature 440 in structure 400 using any of the techniques previously described.

In embodiments, multiple features 440 may be etched to connect multiple portions of the first interconnect 410 to the second interconnect 420. For example, method 300 may include etching a first feature 440a following by etching a second feature 440b into the structure 400. Again, the second feature 440b may be non-orthogonal relative to the substrate 405. That is, the feature 440b, such as a length of the feature 440b, may be tilted or at a non-right angle relative to the substrate 405, such as an upper surface of the substrate 405. The second feature 440b may be formed using any useful etching or removal method. As previously discussed, the second non-orthogonal feature 440b may be unparallel with the non-orthogonal feature, such as first feature 440a. While only two features 440 are illustrated, it is contemplated that any number of features 440 may be included. Additionally, it is contemplated that any number of the features 440 may be nonparallel. For example, structure 400 may include three features 440, four features, five features 440, ten features 440, one hundred features 440, or more that may each be nonparallel to each other.

When multiple unparallel features are etched, method 300 may include multiple iterations of etching that may use different mask materials in order to form features that are unparallel. For example, a first mask material 430 may be used to etch first feature 440a followed by removing the mask material 430 and using a second mask material 430 for etching second feature 440b.

As illustrated in FIG. 4C, after the feature 440 is formed in the structure 400, method 300 may include forming a tilted super via 445 in the feature 440 at operation 315. If the second interconnect 420, is removed during operation 310, the second interconnect 420 may be reformed such that the tilted super via 445 may connect, such as electrically, the first metal-containing feature 410 to the second interconnect 420. The titled super via 445 may be a conductive material, such as a metal-containing material, or a silicon-containing material, such as polysilicon, extending between and electrically and/or physically connecting the first interconnect 410 and the second interconnect 420. The titled super via 445 may be formed using any useful deposition or formation method.

While tilted super via 445 may be illustrated as having a generally consistent profile, it is contemplated that the tilted super via 445 may have other shapes or features. For example, the tilted super via 445 may be non-circular and instead may be oblong, elongated, or tapered. It is also contemplated that the tilted super via 445 may have any other geometry so long as the tilted super via 445 is still tilted as described throughout the present disclosure.

In embodiments having multiple features 440, method 300 may include forming a first titled super via 445a and a second tilted super via 445b. Forming the first titled super via 445a and the second tilted super via 445b may include any of the features previously discussed with regard to operation 315.

During processing, such as after operation 310 or operation 315, the method 300 may include removing or stripping the mask material 430 used to etch the feature 440 as illustrated in FIG. 4C.

The tilted super via 445 (as well as feature 440 formed at operation 310) may be characterized by an angle relative to the substrate of less than or about 90°, such as less than or about 89°, less than or about 88°, less than or about 86°, less than or about 84°, less than or about 82°, less than or about 80°, less than or about 76°, less than or about 76°, less than or about 72°, less than or about 70°, or less. Smaller angles may be difficult to etch during method 300 and may result in a titled super via 445 that spans a long distance between two interconnects, which may reduce electrical performance of a final device. In embodiments, the tilted super via 445 may be characterized by an angle relative to the substrate of greater than or about 60°, such as greater than or about 62°, greater than or about 64°, greater than or about 66°, greater than or about 68°, greater than or about 70°, greater than or about 72°, greater than or about 74°, greater than or about 76°, greater than or about 78°, greater than or about 80°, greater than or about 82°, greater than or about 84°, greater than or about 86°, greater than or about 88°, greater than or about 89°, or more.

The first interconnect 410 and the second interconnect 420 may be connected without an intermediate layer. In conventional technologies, intermediate routing layers, such as third interconnect 425, may be needed to connect, such as electrically, the interconnects on different pitches. In bypassing an intermediate layer, such as third interconnect 425, metal routing density may be improved in final devices. Additionally, the use of tilted super vias 445 may save on parasitics of intermediate layers are able to be bypassed. Further, devices incorporating tilted super vias 445 may not have intermediate layers, therefore reducing resistance and capacitance, such as in a via connecting the first interconnect 410 and the second interconnect 420.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. “About” and/or “approximately” as used herein when referring to a measurable value such as an amount, a temporal duration, and the like, encompasses variations of ±20% or ±10%, ±5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or +0.1% from the specified value, as such variations are appropriate to in the context of the systems, devices, circuits, methods, and other implementations described herein.

As used herein and in the appended claims, the singular forms “a”, “an”, and “the” include plural references unless the context clearly dictates otherwise. Thus, for example, reference to “an insulator material” includes a plurality of such materials, and reference to “the tilted super via” includes reference to one or more tilted super vias and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor structure comprising:
a substrate;
a first interconnect;
an insulator material;
a second interconnect separated from the first interconnect by the insulator material;
a tilted super via connecting the first interconnect to the second interconnect; and
a third interconnect disposed between the first interconnect and the second interconnect, wherein the tilted super via bypasses the third interconnect.

2. The semiconductor structure of claim 1, wherein the first interconnect and the second interconnect are vertically separated by the insulator material.

3. The semiconductor structure of claim 1, wherein the first interconnect and the second interconnect are horizontally separated by the insulator material.

4. The semiconductor structure of claim 1, wherein the first interconnect and the second interconnect are routing layers characterized by different pitches.

5. The semiconductor structure of claim 1, wherein the first interconnect is parallel to the second interconnect.

6. The semiconductor structure of claim 1, further comprising: a second tilted super via connecting a second portion of the first interconnect to a second portion of the second interconnect, wherein the tilted super via and the second tilted super via are nonparallel.

7. The semiconductor structure of claim 1, wherein the first interconnect and the second interconnect are connected without an intermediate layer.

8. The semiconductor structure of claim 1, wherein the tilted super via is characterized by an angle relative to the substrate of less than or about 90°.

9. The semiconductor structure of claim 8, wherein the tilted super via is characterized by an angle relative to the substrate of greater than or about 60°.

10. The semiconductor structure of claim 1, wherein the insulator material comprises a silicon-containing material.

11. A semiconductor processing method comprising:
forming a semiconductor structure comprising:
a substrate;
a first interconnect;
an insulator material; and
a second interconnect separated from the first interconnect by the insulator material;
etching a non-orthogonal feature into the semiconductor structure; and
forming a tilted super via in the non-orthogonal feature that connects the first interconnect to the second interconnect.

12. The semiconductor processing method of claim 11, wherein the first interconnect is parallel to the second interconnect.

13. The semiconductor processing method of claim 11, wherein the first interconnect and the second interconnect are connected without an intermediate layer.

14. The semiconductor processing method of claim 11, wherein the semiconductor structure further comprises a third interconnect disposed between the first interconnect and the second interconnect, wherein the tilted super via bypasses the third interconnect.

15. The semiconductor processing method of claim 11, wherein the tilted super via is characterized by an angle relative to the substrate of between about 60° and about 89°.

16. The semiconductor processing method of claim 11, further comprising: etching a second non-orthogonal feature into the semiconductor structure, wherein the second non-orthogonal feature is unparallel with the non-orthogonal feature; and forming a second tilted super via in the non-orthogonal feature that connects a second portion of the first interconnect to a second portion of the second interconnect.

17. A semiconductor structure comprising:
a substrate;
a first metal-containing routing layer;
an insulator material;
a second metal-containing routing layer parallel to the first metal-containing routing layer and vertically separated from the first metal-containing routing layer by the insulator material;
a first tilted super via connecting a first portion of the first metal-containing routing layer to a first portion of the second metal-containing routing layer; and
a second tilted super via connecting a second portion of the first metal-containing routing layer to a second portion of the second metal-containing routing layer, wherein the first tilted super via and the second tilted super via are unparallel.

18. The semiconductor structure of claim 17, wherein the first tilted super via and the second tilted super via bypass a third metal-containing routing layer disposed between the first metal-containing routing layer and the second metal-containing routing layer.

19. The semiconductor structure of claim 17, wherein the first metal-containing routing layer and the second metal-containing routing layer are connected without an intermediate routing layer.

20. The semiconductor structure of claim 17, wherein the first tilted super via and the second tilted super via are characterized by an angle relative to the substrate of between about 60° and about 89°.
